(19) United States
(12) Patent Application Publication
(10) Pub. No.: US 2007/0018718 A1
(43) Pub. Date: Jan. 25, 2007

(54) Microwave transmitter and the method for increasing envelope bandwidth

(75) Inventors: Tzyy-Sheng Horng, Kaohsiung City (TW); Yuan Chen, Jhongli City (TW); Je-Kuan Jau, Tainan City (TW); Jian-Yu Li, Chaojhou Township (TW); Chang-Ming Lai, Chiayi City (TW)

Correspondence Address: BACON & THOMAS, PLLC, 625 SLATERS LANE, FOURTH FLOOR, ALEXANDRIA, VA, 22314, US

(73) Assignees: National Sun Yat-sen University, Kaohsiung (TW); Industrial Technology Research Institute, Hsinchu (TW)

(21) Appl. No.: 11/455,046

(22) Filed: Jun. 19, 2006

Related U.S. Application Data
(60) Provisional application No. 60/812,097, filed on Jun. 9, 2006.

(30) Foreign Application Priority Data
Jun. 20, 2005 (TW) 94120407

(51) Int. Cl. H03F 3/38

(52) U.S. Cl. 330/10

(57) ABSTRACT

The microwave transmitter of the present invention can perform two-terminal dynamic modulation with respect to the voltage supply terminal and the RF input terminal of a RF power amplifier. The microwave transmitter of the present invention comprises a first modulator and a second modulator. The first modulator uses the baseband digital delta-sigma modulation technique to process the envelope signal and outputs this signal to the voltage supply terminal of the RF power amplifier as a supply voltage. The second modulator uses the baseband digital pre-distortion technique to process the IQ-modulated carrier and outputs this signal to the RF input terminal of the RF power amplifier as a RF input signal. Thereby, the RF power amplifier can highly efficiently reconstruct the power-amplified RF modulated carrier without distortion at the RF output terminal. In addition, the baseband digital processing techniques used in the two modulators make the microwave transmitter of the present invention suitable for multi-mode operation.

### BACKGROUND OF THE INVENTION

1. Field of the Invention

The present invention relates to a microwave transmitter and, more specifically, to a microwave and a method thereof applicable to various transmitter specifications for wireless communication systems, to attain the function of multi-mode transmission.

2. Description of Related Art

In wireless communication handset apparatuses, the major DC (direct-current) power loss results from RF (radio-frequency) power amplifiers. Therefore, one key point of the research on the design of an RF power amplifier always lies in that the RF power amplifier has high linearity without distorting the amplified signal, and has high efficiency to extend the communication time as well. In particular, the digital modulation technique of orthogonal frequency division multiplex (OFDM), which will be widely adopted in the future wireless communication systems, is characterized by significant time-varying envelopes, with a peak-average power ratio (PAPR) much higher than one for the existing wireless communication systems. In other words, the envelopes for OFDM may vary more drastically with time and may consequently require higher linearity for the RF power amplifier.

According to the prior art, the traditional type of design for an RF power amplifier may follow the trade-off between the linearity and the efficiency thereof, wherein a required increase in the linearity would necessarily lead to a decrease in the efficiency. Especially when the power of a traditional microwave transmitter is controlled to have an output of small power, the DC bias is still kept at a voltage for an output of large power, thereby resulting in excessive DC power dissipation so that the RF power amplifier has a decreased efficiency of its dynamic operation.

In the light of such a problem, ROC Patent No. 578369 discloses a high-efficiency power amplifier system, which may dynamically adjust the voltage supply for the RF power amplifier according to the magnitude of the output of power, to decrease the power dissipation resulting from the DC bias for an output of small power. However, for amplifying an RF modulated carrier with time-varying envelopes, it is further necessary that the voltage supply for the RF power amplifier is adjusted in following up the variation of the envelope magnitude of the output RF modulated carrier so as to greatly increase the efficiency of the dynamic operation.

Thus, the well-known envelope elimination restoration (EER) architecture of transmitter in the existing literature applies switched RF power amplifiers, e.g., class-D, class-E and class-F amplifiers, which have the characteristic that the amplitude of the output RF carrier is proportional to the voltage supply. As a result, the envelope signal of the input RF modulated carrier and the carrier that contains the information of the phase can be separated from each other and transmitted to the voltage supply terminal and the RF input terminal of the RF power amplifier, respectively, so that the envelope signal of the input RF modulated carrier can modulate the voltage supply terminal dynamically for the RF power amplifier to fulfill the purpose to have highly dynamic operation efficiency.

Referring to FIG. 1, a block diagram of an EER architecture of transmitter is shown with a technique that employs an analog circuit to separate the envelope signal and the phase-modulated carrier. After the RF modulated carrier with time-varying envelopes from the input terminal passes an envelope detector 101 and a limiter 102, it can be separated into a low-frequency envelope signal 103 and a constant-envelope phase-modulated carrier 104, wherein the envelope signal 103 goes to pass a class-S modulator 105 to modulate the voltage supply terminal of a switched RF power amplifier 106 while the phase-modulated carrier 104, as having been constant-envelope, can be power amplified by the switched RF power amplifier 106 in highly efficient operation. By the characteristic that the amplitude of the output RF carrier of the switched RF power amplifier 106 is proportional to the DC voltage supply, the envelope signal is combined with the amplified phase-modulated carrier so that an RF modulated carrier 107 that is provided with the original time-varying envelopes after amplification is obtained at the output terminal of the transmitter.

In the block diagram as shown in FIG. 2, the architecture of the class-S modulator 105 comprises a pulse-width modulator 201, a switched amplifier 202 and a low-pass filter 203. The pulse-width modulator 201 converts the input envelope signal into a two-stage pulse signal that has a pulse width proportional to the magnitude of the input envelope signal. The two-stage pulse signal is amplified through the switched amplifier 202 and, then, passes the low-pass filter 203, so as an amplified envelope signal is obtained. This architecture is characterized by high linearity and high efficiency but is suitable for amplifying the low-frequency envelope signal 103 only. Because the EER transmitter uses the switched RF power amplifier 106 and the class-S modulator 105, of which each is characterized by high efficiency and can reduce excessive DC power dissipation effectively, it is quite applicable to a variety of wireless communication handset apparatuses.

However, the EER transmitter according to the prior art applies the analogy technique to separate the envelope signal 103 from the phase-modulated carrier 104 and ultimately reconstructs the RF modulated carrier 107 at the output terminal, the obtained RF modulated carrier 107 has modulation accuracy not better than the traditional microwave transmitter that applies the IQ-modulation technique, where “I” is the in-phase component of the waveform, and “Q” represents the quadrature component. After the envelope signal 103 passes the low-pass filter 203 of the class-S modulator 105, the high-frequency components of the envelope signal 103 would be filtered off so that the amplified envelope signal would be distorted for the low-voltage region with high-frequency components, as shown in FIG. 3. The original very deep depressed position of the region is irreproducible and, thus, it would cause spectral regrowth for the RF modulated carrier 107 at the output terminal and would hardly conform to the standard for the output spectra for wireless communication systems. In addition, the pulse-width modulator 201 need use a source capable of generating triangle waves and this would raise the complexity in realizing the system and increase the chance of a distortion of the RF modulated carrier 107 at the output terminal.

For better modulation accuracy, U.S. Pat. No. 6,377,784 provides a polar modulation architecture, as shown in FIG. 4. This architecture has a cartesian-to-polar converter 401 that is realized with the baseband digital technique, such that the input IQ signals can be precisely converted into the corresponding envelope signal and phase signal. The envelope signal is sent to a linear voltage modulator 402 after a digital-to-analog conversion, for dynamically adjusting the voltage supply for an RF power amplifier 404 in following up the variation of the envelope magnitude. On the other hand, the phase signal is sent to a frequency generator 403 having the function of phase modulation, to generate a phase-modulated carrier and then is sent to the RF input terminal of the RF power amplifier 404. As compared with the EER architecture of transmitter, the polar modulation architecture adopts the baseband digital technique to precisely separate the envelope signal from the phase signal and, therefore, higher modulation accuracy can be achieved for the RF modulated carrier at the output terminal. However, the linear voltage modulator 402 to use is not as good as the class-S modulator 105 that is characterized by high efficiency, so that the associated transmitter usually has an efficiency lower than the EER transmitter has.

Besides, in case of a modulation signal characterized by zero-crossing, such as QPSK or QAM, its phase would drastically change by 180° when the vector locus of the signal gets across the zero. Now the frequency generator 403 having the function of phase modulation typically cannot afford an adequate bandwidth for generating a phase-modulated carrier that has a drastically changing phase. Therefore, currently the polar modulation architecture is applicable successively to the multi-mode communication system that is not characterized by zero-crossing, such as the 2G-GSM and 2.5G-EDGE dual-mode transmitters, but is not applicable to the wireless communication system that employs a zero-crossing modulation signal, such as the 2G-GSM and 3G-CDMA dual-mode transmitters.

In the EER architecture of transmitter, when the supply voltage terminal of the switched RF power amplifier 106 is meeting a higher voltage of the envelope signal 103, the RF input terminal of the switched RF power amplifier 106 would requires a higher power of the input phase-modulated carrier 104 so as for the transistor to switch between a saturation region and a cutoff region while keeping the switched RF power amplifier 106 in a high-efficiency mode of operation. However, when the supply voltage terminal is meeting a lower voltage of the envelope signal 103, an equal power of the input phase-modulated carrier 104 would make both the gain and the efficiency of the switched RF power amplifier 106 decreased instead while causing the phase-modulated carrier 104 at the RF input terminal to leak to the output terminal, with an influence on the quality of the RF modulated carrier 107 at the output terminal. So, for the EER architecture of transmitter, U.S. Pat. No. 6,256,482 provides a method of dynamically adjusting the power of the phase-modulated carrier at the RF input terminal depending on the envelope magnitude that can effectively improve the efficiency of the dynamic operation for the EER transmitter but, it provides no solution to the problem described above that the EER architecture lacks modulation accuracy.

### SUMMARY OF THE INVENTION

The RF power amplifier used in traditional microwave transmitters needs a trade-off between linearity and efficiency, whereas the EER architecture of transmitter has the advantage that both high linearity and high efficiency can be achieved. However, the main disadvantages of the EER architecture of transmitter include inadequate modulation accuracy, distortion that easily occurs the envelope signal is processed by the pulse-width modulator, decrease in the efficiency of dynamic operation due to fixing the power of the input carrier, and leakage of the carrier. However, no methods currently presented can overcome these disadvantages completely.

In view of this, the present invention provides a novel architecture of microwave transmitter, which largely introduces the baseband digital processing technique, as being capable of not only increasing the modulation precision for the signal but also adapting to various modulation specifications for wireless communication systems to attain the function of multi-mode transmission.

It is one object of the present invention to provide an architecture of microwave transmitter to improve the EER architecture of transmitter, by largely introducing the baseband digital processing technique to promote the tailor-made degree for IC (integrated circuit) design.

It is another object of the present invention to provide a architecture of microwave transmitter to improve the EER architecture of transmitter, by utilizing the baseband digital delta-sigma modulation technique to promote the accuracy and amplification efficiency for the envelope signal and by utilizing the pre-distortion technique to endow the pre-distorted IQ-modulated carrier with a time-varying characteristic so that the power of the input carrier can be adjusted flexibly and, thereby, the problems with respect to the efficiency of dynamic operation and the leakage of the carrier can be reformed.

To fulfill the purpose described above, the microwave transmitter of the present invention performs a two-terminal dynamic modulation with respect to the voltage supply terminal and the RF input terminal of a RF power amplifier, the modes of modulation including envelope modulation, phase modulation and IQ modulation, wherein the modulated signal at the voltage supply terminal may be an envelope signal, a pre-distorted envelope signal, or a modulated signal containing components of envelopes, while the modulated signal at the RF input terminal may be an IQ-modulated carrier, a pre-distorted IQ-modulated carrier, a phase-modulated carrier, a pre-distorted phase-modulated carrier, or a phase-modulated carrier containing components of envelopes.

The microwave transmitter of the present invention has the envelope signal generated directly by a baseband digital processor and processed by a digital delta-sigma modulator instead of the pulse-width modulator as required, wherein the digital delta-sigma modulator does not need a source of triangle waves and, thus, can be integrated into the baseband digital circuit.

Further, the microwave transmitter of the present invention replaces the phase-modulated carrier having constant envelope magnitude with the pre-distorted IQ-modulated carrier for input to the RF input terminal of the RF power amplifier, endowing the pre-distorted IQ-modulated carrier with a time-varying characteristic so that the power of the input carrier can be adjusted flexibly and, thereby, the problems with respect to decrease in the efficiency of dynamic operation and leakage of the carrier can be reformed, wherein the IQ-modulated carrier, as having been processed with the pre-distortion technique, is combined with the envelope signal for the RF power amplifier to reconstruct the power-amplified RF modulated carrier without distortion at the RF output terminal.

The microwave transmitter realized according to the present invention and the wireless communication handset apparatus performed in light of the teaching of the present invention can reform the disadvantage of the existing EER architecture of transmitter with baseband digital technique, in contrast to the trade-off between high linearity and high efficiency of traditional microwave transmitters. Except for keeping the characteristic that both high linearity and high efficiency can be achieved, the present invention further promotes the quality of the output RF modulated carrier and the efficiency of the dynamic operation and, also, adapts more easily to various modulation specifications for wireless communication systems to attain the function of multi-mode transmission.

### BRIEF DESCRIPTION OF THE DRAWINGS

FIG. 1 is a block diagram of an envelope elimination restoration (EER) architecture of transmitter.

FIG. 2 is a block diagram of the architecture of class-S modulator shown in FIG. 1.

FIG. 3 is a timing diagram of an amplified envelope signal that has passed a class-S modulator.

FIG. 4 is a block diagram of a polar modulation architecture.

FIG. 5 is a block diagram of the architecture of transmitter of the present invention.

FIG. 6 is an architecture diagram of the delta-sigma modulator required in processing the envelope signal according the present invention.

FIG. 7 is a schematic diagram showing the concept of operating the transmitter of the present invention.

FIG. 8 is a block diagram of the transceiver chip of the wireless handset apparatus performed according to the teaching of the present invention.

FIG. 9 is another block diagram of the transceiver chip of the wireless handset apparatus performed according to the teaching of the present invention.

FIG. 10 is a diagram showing the test results of the error vector magnitude (EVM), the adjacent channel power ratio (ACPR) and the conversion efficiency (ConvEff) of DC power to RF power for the hardware implementation realized according to the teaching of the present invention.

FIG. 11 is a block diagram of the architecture of transmitter that increases the bandwidth for the envelope according to the present invention.

FIG. 12 is a block diagram of the architecture of transmitter that is provided with a feedback control according to the present invention.

FIG. 13 is a block diagram of the architecture of transmitter that is provided with a feedback control and increases the bandwidth for the envelope according to the present invention.

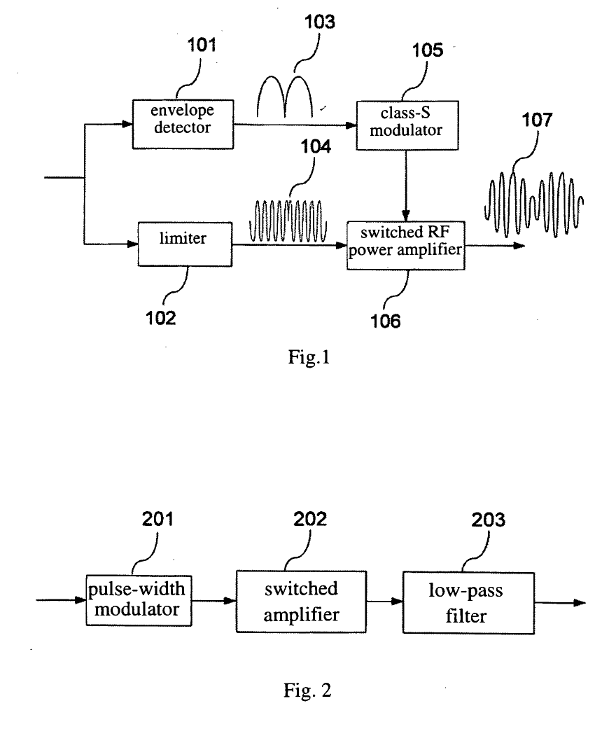

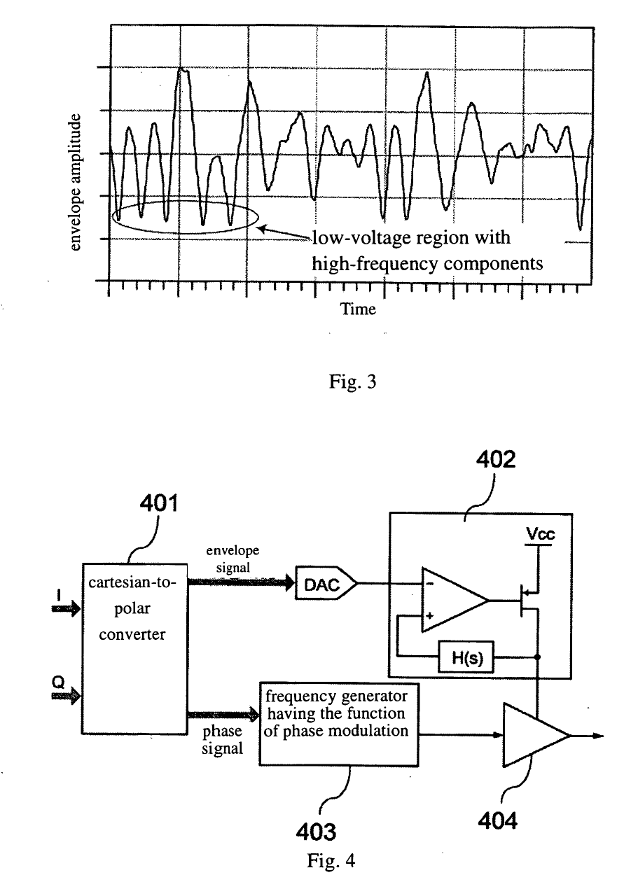

### DETAILED DESCRIPTION OF THE EMBODIMENTS

Although the present invention will be full described by reference to the appended drawings for preferred embodiments of the present invention, it will be understood before the description that those skilled in the art may modify the invention described herein while acquire the function of the present invention. Therefore, it will be understood that the following description is a general disclosure to those skilled in the art and, thus, the structure of the present invention should be applicable to different architectures of microwave transmitter. The application of the present invention should not be only limited to the preferred embodiments in the following description.

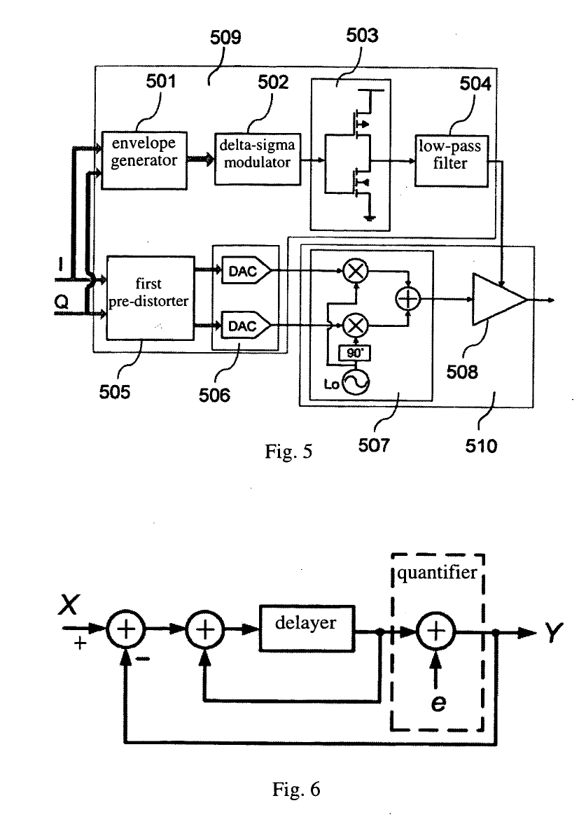

First, referring to FIG. 5, it shows a block diagram of the architecture of multi-mode microwave transmitter of the present invention. In a preferred embodiment of the present invention, the architecture of transmitter has totally two paths for signal processing, wherein one is for the envelope signal processing, another is for the pre-distorted IQ modulated signal processing and both the two paths perform a two-terminal dynamic modulation with respect to the voltage supply terminal and the RF input terminal of a RF power amplifier. Along the path for the envelope signal processing, the architecture of the present invention comprises an envelope generator 501, a delta-sigma modulator 502, a switched amplifier 503 and a low-pass filter 504. The present invention has the input IQ signals passing the envelope generator 501 to generate the corresponding envelope signal, for which the baseband envelope signal may be expressed by the following expression:
E=\sqrt{I²Q²}. (1)
In (1), E is given as the amplitude in the polar coordinate and, also, represents the envelope signal corresponding to the input IQ signals, wherein the operations of squaring and rooting are not easy to achieve with a digital circuit. For this, refer to the CORDIC algorithm disclosed by Ray Andraka in FPGA '98. Proceedings of the 1998 ACM/SIGDA Sixth International Symposium on Field Programmable Gate Arrays, pp. 191-200 (22-24, Feb. 1998), wherein the desired magnitude of the envelope is successively approximated by iteration. Then the digital envelope signal obtained passes the delta-sigma modulator 502 to convert to a two-stage signal. The architecture of the delta-sigma modulator 502 is shown by reference to FIG. 6. The delta-sigma modulator may be an analog delta-sigma modulator, an analog pulse-width modulator, an analog multi-stage delta-sigma modulator, a digital delta-sigma modulator, a digital pulse-width modulator and a digital multi-stage delta-sigma modulator.

FIG. 6 shows a two-stage delta-sigma modulator, wherein the input signal X is integrated and, then, determined by a quantifier to be output as ‘1’ if it is beyond a quantification level, or ‘0’ on the contrary, and the output result is fed to the input terminal as negative feedback. This is the action of difference, for which the transfer function can be expressed as follows:
Y=X+(1−z⁻¹)e, (2)
where e represents the quantified noise introduced by the quantifier. From (2), it is found that the output signal Y equals to the input signal X plus the quantified noise after difference while the difference is equivalent to an action of driving the energy of the signal toward high frequency in the frequency domain. The signal Y obtained at the output terminal is a two-stage pulse wave signal being applicable to the high-efficiency switched amplifier 503 for amplification, and, as it passes the low-pass filter 504 to have the quantified noise that have been driven towards high frequency filtered off, an amplified input envelope waveform is obtained. This amplified envelope signal is input to the voltage supply terminal of an RF power amplifier 508, so that the carrier output from the RF power amplifier 508 is amplitude-modulated by the time-varying envelope signal from the voltage supply terminal.

Along the path for the pre-distorted IQ modulated signal processing, the architecture of transmitter of the present invention comprises a first pre-distorter 505, a plurality of digital-to-analog converters 506 and an IQ-modulator 507. The present invention has the input IQ signals passing the digital first pre-distorter 505 and then has the pre-distorted IQ signals converted to the corresponding analog signal through the plurality of digital-to-analog converters 506, thereby producing the IQ-modulated carrier with the IQ-modulator 507 as a signal at the RF input terminal of an RF power amplifier 508. This endows the input carrier with a time-varying envelope characteristic so that the power of the input carrier can be adjusted flexibly and, thereby, the problems with respect to the efficiency of dynamic operation and the leakage of the carrier can be reformed. Nevertheless, the IQ-modulated carrier, as having been processed with the pre-distortion technique, is combined with the envelope signal for the RF power amplifier 508 to reconstruct the power-amplified RF modulated carrier without distortion at the output terminal. In different embodiments of the present invention, it is as well that the input IQ signals pass the first pre-distorter 505 at first and the output signals are then input to the envelope generator 501 and the plurality of digital-to-analog converters 506, respectively.

In the architecture of multi-mode microwave transmitter of the present invention, the first pre-distorter 505 uses the digital technique to compensate the nonlinear relation between the input and output signals of the transmitter. The major causes come from the nonlinear phenomena in the RF power amplifier 508, which may be the amplifier circuit such as one of class-A, class-B, class-AB, class-C, class-D, class-E or class-F. The circuitry functions of the first pre-distorter 505 include changing the IQ baseband signal, the envelope signal, the phase signal or the amplitude of the RF carrier, for compensating the nonlinear phenomena of the elements contained in the transmitter circuit and thereby seeking an improvement of the parameters, e.g., the modulation accuracy and the linearity, of the RF-modulated carrier at the output terminal.

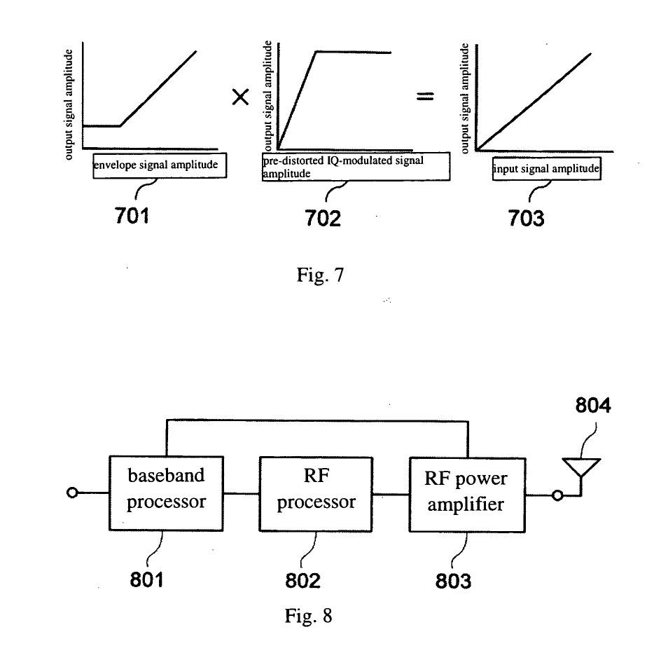

FIG. 7 is a schematic diagram showing the concept of operating the transmitter of the present invention. The characteristic variation of the output signal amplitude vs. the envelope amplitude is as shown in characteristic 701, wherein the output signal amplitude has a fixed lower limit at low envelope amplitudes since the signal of the RF carrier at the input terminal would leak to the output terminal while the output signal amplitude has a linear relation to the envelope amplitude at high envelope amplitudes. The pre-distorter can result in a relation of the output signal amplitude vs. the pre-distorted IQ-modulated signal amplitude as shown in characteristic 702, wherein a linear relation is presented at low output signal amplitudes while saturation with a fixed upper limit is facilitated at high output signal amplitudes. Characteristics 702 and 703 present a compensation relation in the form of multiplication exactly. Thus, when the signals along the two paths meet at the RF power amplifier 508, an ideally linear relation of the output signal amplitude vs. the input signal amplitude can be acquired, as shown in characteristic 703.

The embodiments of the present invention have advantages in achieving hardware implementation, including that the adopted envelope generator 501, the delta-sigma modulator 502 and the first pre-distorter 505 are realized in a manner of the baseband digital processing, that the high-efficiency switched amplifier 503 and the low-pass filter 504 may be realized by using the baseband analog signal processing technique, and the plurality of digital-to-analog converters 506 is realized by using the baseband mixed signal processing technique, wherein those circuits may be altogether referred to as a multi-mode operation efficiency promoting baseband processor 509. Since the existing design of the baseband signal-processing chip would lead to functions that may be fairly powerful, which tend to meet various modulation specifications for wireless communication systems, the technique of the present invention may suitably apply to the multi-mode wireless systems. If the multi-mode operation efficiency promoting baseband processor 509 is disabled, then the remaining IQ-modulator 507 and RF power amplifier 508 may be combined to be a traditional architecture of IQ-modulated microwave transmitter 510 that has low efficiency but high linearity; if the multi-mode operation efficiency promoting baseband processor 509 is enabled, then it is improved to be a architecture of multi-mode microwave transmitter that achieves both high efficiency and high linearity. This means that the traditional architecture of IQ-modulated microwave transmitter may be deemed a special example of the present embodiment and can be extended to two architectures of transceiver chip of a wireless handset apparatus, as further described in the following.

Referring FIG. 8, it shows a block diagram of the transceiver chip of the wireless handset apparatus realizing the transmitter of the present invention. According to the teaching of the present invention, the architecture of low-efficiency transmitter adopted in the traditional transceiver chip of the wireless handset apparatus can be extended from the original baseband circuit to the architecture of high-efficiency transmitter of the present invention. The transceiver chip of the wireless handset apparatus comprises a baseband processor 801, an RF processor 802 and an RF power amplifier 803, wherein the RF power amplifier 803 has its output terminal connected to an antenna 804 for transmitting the signals. Based on the integration function of the baseband signal processing chip design, the wireless handset can have a transmitter efficiency promoted greatly and also be suitable for multi-mode operation, provided that the circuit of the multi-mode operation efficiency promoting baseband processor 509 is realized in the baseband processor 801.

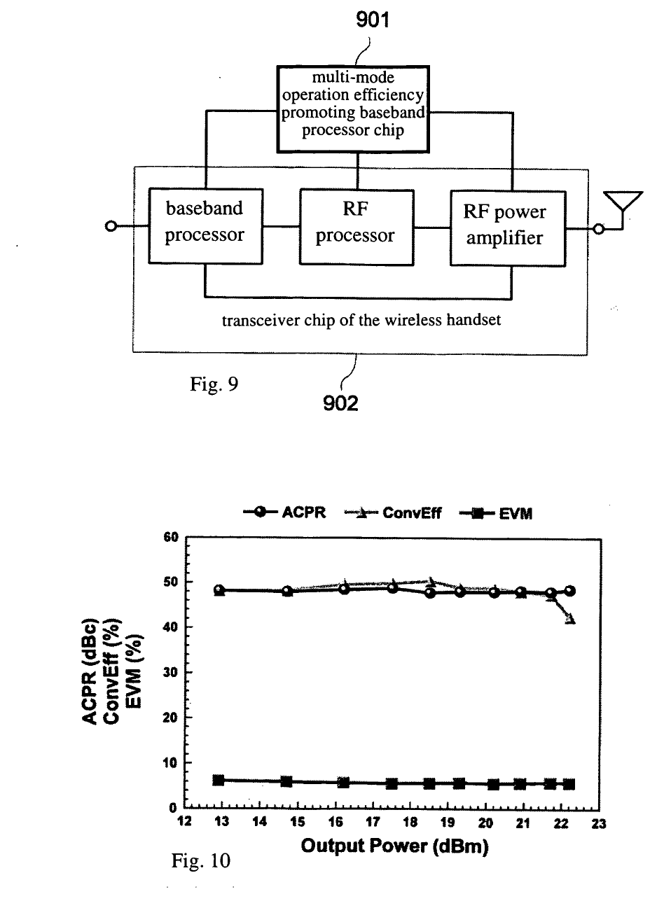

Referring FIG. 9, it shows another block diagram of the transceiver chip of the wireless handset apparatus realizing the transmitter of the present invention. With an unchanged architecture of the traditional transceiver chip of the wireless handset 902, the multi-mode operation efficiency promoting baseband processor 509 can be developed alone to be a multi-mode operation efficiency promoting baseband processor chip 901 according to the teaching of the present invention. As shown in FIG. 9, the chip 901 can operate in coordination with the transceiver chip of the wireless handset 902, in order that the wireless handset have a transmitter efficiency promoted greatly under multi-mode operation as well.

According to the embodiments shown in FIG. 5, the present invention has accomplished in hardware implementation a high-efficiency microwave transmitter that has a PCS (personal communication service) band of 1.9 GHz applied to a CDMA2000 1× system and is provided with a function of power control, wherein the baseband digital technique is performed with a field-programmable gate array (FPGA) while other mixed signals and the analog circuit are realized with the present IC product. For the test for the transmitter integration, with FPGA a QPSK(quadrature phase shift keying) modulated signal containing a data rate 1.2288 M symbols/s is generated as the baseband input signal. Besides, the switched amplifier 503 that amplifies the envelope signal has a DC voltage supply setting related to the output power of the transmitter; that is, the larger the output power is, the larger envelope amplitude and, accordingly, the larger the DC voltage supply value would be required.

FIG. 10 shows the test results for the case that the transmitted power is in a control range from 13 dBm to 22 dBm, when the DC voltage supply value is set at 3.3 V. The test parameters include the error vector magnitude (EVM) for measuring the modulation accuracy, the adjacent channel power ratio (ACPR) for measuring the linearity, and the conversion efficiency (ConvEff) of DC power to RF power for measuring the transmitter efficiency. In FIG. 10, the EVM value is about 5.8%, the ACPR value is about 48 dBc, both satisfying the specification of the CDMA2000 1× system. The EVM and ACPR values can be improved continually, if the first pre-distorter 505 is adjusted continually. Within the specified power control range, the ConvEff value is near 48%, which is reduced to a power-added efficiency (PAE) of 45% by conversion, manifesting a transmitter efficiency much more superior than that of the existing product.

In addition, an important characteristic of the transmitter of the present invention may be found from FIG. 10. That is, for it the EVM, ACPR and ConvEff values all are independent of the output power nearly. For the architecture of the traditional microwave transmitter, these electric parameters would have close dependence on the output power and, moreover, the EVM and ACPR values have a trade-off relation to the efficiency (ConvEff or PAE). Thus, the microwave transmitter of the present invention has the advantage that the quality of the electric parameters can be held fixed for different requirements on the output power in different modes of operation.

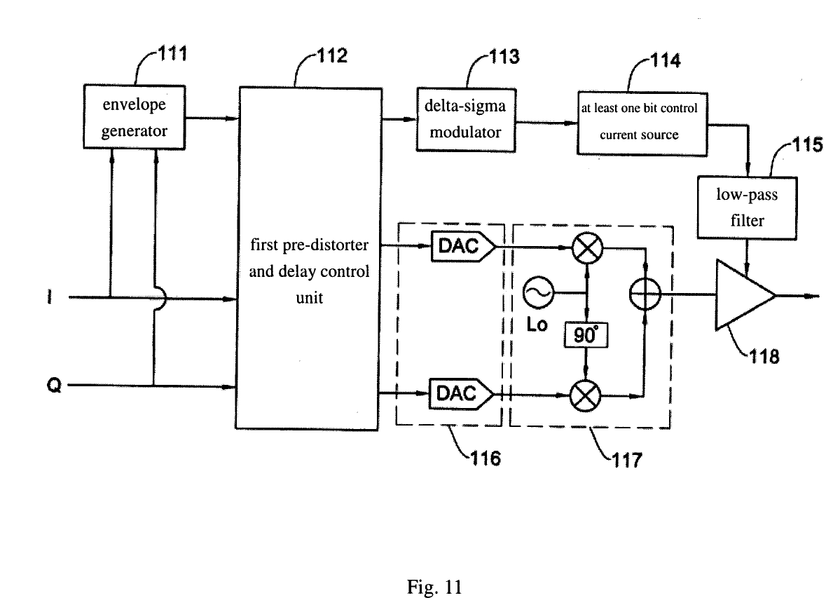

Referring FIG. 11, it is a block diagram showing the architecture of the microwave transmitter of the present invention that increases the bandwidth for the envelope. This embodiment is an improved embodiment shown in FIG. 5, allowing the microwave transmitter to have an increased data transfer rate. The architecture of transmitter similarly has two paths for signal processing, wherein one is for the envelope signal processing, another is for the pre-distorted and delayed IQ modulated signal processing and both the two paths perform a two-terminal dynamic modulation with respect to the current supply terminal and the RF input terminal of a RF power amplifier. Along the path for the envelope signal processing, the architecture of transmitter of the present invention comprises an envelope generator 111, a first pre-distorter and delay control unit 112, a delta-sigma modulator 113, an at least one bit control current source 114 and a low-pass filter 115. The present invention has the input IQ signals passing the envelope generator 111 to generate the corresponding envelope signal. The digital envelope signal obtained passes the first pre-distorter and delay control unit 112 and then passes the delta-sigma modulator 113 to convert to an at least two-stage signal, wherein the delta-sigma modulator 113 that has at least two-stage output can reduce the over-sample rate required in difference-integration. For the same working frequency of the delta-sigma modulator 113, the more-stage output can bring about the higher data transfer rate so that this architecture is more suitable for a communication system having a high data transfer rate. The signal at the output terminal of the delta-sigma modulator 113 is an at least two-stage pulse wave signal, being converted to a current supply for an RF power amplifier 118 by using the at least one bit control current source 114, and, as it passes the low-pass filter 115 to have the quantified noise that have been driven towards high frequency filtered off, an amplified input envelope waveform is obtained. This envelope signal is the current supply for the RF power amplifier 118, for which the current supply is controlled to fulfill the purpose to control the RF power amplifier 118, so that the carrier output from the RF power amplifier 118 is amplitude-modulated by the time-varying envelope signal from the current supply terminal.

Along the path for the pre-distorted and delayed IQ modulated signal processing, the architecture of transmitter of the present invention comprises a first pre-distorter and delay control unit 112, a plurality of digital-to-analog converters 116 and a IQ-modulator 117. The present invention has the input IQ signals passing the first pre-distorter and delay control unit 112, and then has the pre-distorted and delay-corrected IQ signals converted to the corresponding analog signals through the plurality of digital-to-analog converters 116, thereby producing the IQ-modulated carrier with the IQ-modulator 117, as a signal at the RF input terminal of the RF power amplifier 118. This endows the input carrier with a time-varying envelope characteristic so that the power of the input carrier can be adjusted flexibly and, thereby, the problems with respect to the efficiency of dynamic operation and the leakage of the carrier can be reformed. Nevertheless, the IQ-modulated carrier, as having been processed with the pre-distortion technique, is combined with the envelope signal for the RF power amplifier 118 to reconstruct the power-amplified RF modulated carrier without distortion at the output terminal. Said delay control unit is used for coordinating the two paths for signal processing, so as to synchronize the signals along the twp paths. In different embodiments of the present invention, it is as well that the input IQ signals pass the first pre-distorter at first and the output signals are then input to the envelope generator and the plurality of digital-to-analog converters, respectively.

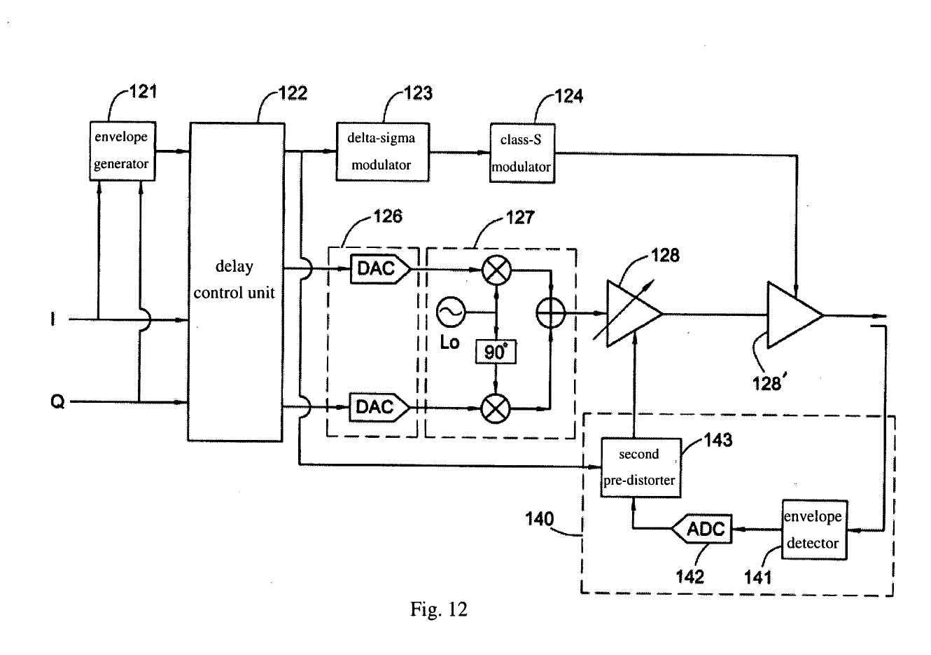

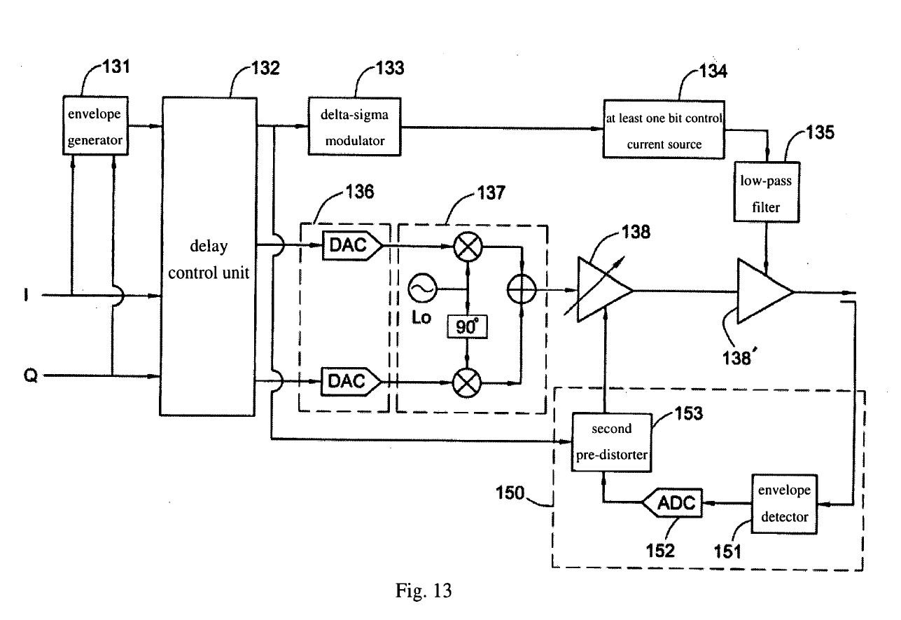

Because of the process-drift problem in the manufacturing process, the elements would show slight variations; in use of the circuits, the temperature would often change with the change in the environment and the operation time. With a variety of change in the external environment, the characteristic of the circuits would also change significantly and, therefore, the output of the RF power amplifier can be feedback to the pre-distorter under the requirement for robustness, as shown in FIGS. 12 and 13. This path for feedback comprises a feedback control unit, which further comprises an envelope detector, an analog-to-digital converter and a second pre-distorter. The output of the RF power amplifier contains the influence that all the circuits have undergone in various environments. By the envelope detector, this signal is converted to have a low frequency and, then, by the analog-to-digital converter, this analog signal is converted to a digital signal. Then, the most suitable control signal is found out adaptively in a digital manner to modulate the input terminal of the RF power amplifier. The path for feedback can dynamically monitor the change of the circuits and improve the linearity of the power amplifier, as further described in the following.

Referring to FIG. 12, it is a block diagram showing the architecture of microwave transmitter that is provided with a feedback control according to the present invention. In this embodiment of the present, the microwave transmitter is such as to have a feedback control for improving the linearity of the power amplifier. The architecture of transmitter has two paths for signal processing, wherein one is for the envelope signal processing, another is for the delayed IQ modulated signal processing and both the two paths perform a two-terminal dynamic modulation with respect to the voltage supply terminal and the RF input terminal of a RF power amplifier. Along the path for the envelope signal processing, the architecture of transmitter of the present invention comprises an envelope generator 121, a delay control unit 122, a delta-sigma modulator 123, and a class-S modulator 124. The present invention has the input IQ signals passing the envelope generator 121 to generate the corresponding envelope signal. The digital envelope signal obtained passes the delay control unit 122 and then passes the delta-sigma modulator 123 to convert to a two-stage signal, and finally it pass through the class-S modulator 124 to modulate the voltage supply terminal of an RF power amplifier 128′, wherein the class-S modulator 124 and the delta-sigma modulator 123 may be described as in FIGS. 2 and 6, not to be given the detail.

Along the path for the delayed IQ modulated signal processing, the architecture of transmitter of the present invention comprises a delay control unit 122, a plurality of digital-to-analog converters 126, a IQ-modulator 127, a tunable gain amplifier 128 and a feedback control unit 140, wherein the feedback control unit 140 comprises an envelope detector 141, an analog-to-digital converter 142 and a second pre-distorter 143. The envelope detector 141 detects the output terminal of the RF power amplifier 128′ to produce the feedback envelope signal, the feedback envelope signal is digitized through the analog-to-digital converter 142, and the digitized feedback envelope signal together with the delayed digital envelope signal from the envelope generator is received by the second pre-distorter 143.

The present invention has the input IQ signals passing the delay control unit 122, and then has the delay-corrected IQ signals converted to the corresponding analog signals through the plurality of digital-to-analog converters 126, thereby producing the IQ-modulated carrier with the IQ-modulator 127, as a signal at the RF input terminal of the RF power amplifier 128′ after amplification by the tunable gain amplifier 128.

The gain of the above-described tunable gain amplifier 128 is determined by the output of the second pre-distorter 143, which receives the output signal from the analog-to-digital converter 142 (digitized feedback envelope signal) and the output delayed signal from the envelope generator 121 (digital envelope signal), to produce a control signal for controlling the gain of the tunable gain amplifier 128. In different embodiments of the present invention, it is as well that the input IQ signals pass the delay control unit at first and the output signals are then input to the envelope generator and the plurality of digital-to-analog converters, respectively.

Referring to FIG. 13, it is a block diagram showing the architecture of microwave transmitter that is provided with a feedback control and increases the bandwidth for the envelope according to the present invention. In this embodiment of the present invention, the microwave transmitter is such as to have a feedback control and an increased data transfer rate. As shown in FIG. 13, the architecture of transmitter has two paths for signal processing, wherein one is for the envelope signal processing, another is for the delayed IQ modulated signal processing and both the two paths perform a two-terminal dynamic modulation with respect to the current supply terminal and the RF input terminal of a RF power amplifier. Along the path for the envelope signal processing, the architecture of transmitter of the present invention comprises an envelope generator 131, a delay control unit 132, a delta-sigma modulator 133, an at least one bit control current source 134 and a low-pass filter 135.

The present invention has the input IQ signals passing the envelope generator 131 to generate the corresponding envelope signal. The digital envelope signal obtained passes the delay control unit 132 and then passes the delta-sigma modulator 133 to convert to an at least two-stage signal. The signal at the output terminal of the delta-sigma modulator 113 is an at least two-stage pulse wave signal, being converted to a current supply for an RF power amplifier 138′ by using the at least one bit control current source 134, and, as it passes the low-pass filter 135 to have the quantified noise that have been driven towards high frequency filtered off, an amplified input envelope waveform is obtained. This envelope signal is the current supply for the RF power amplifier 138′, for which the current supply is controlled to fulfill the purpose to control the RF power amplifier 138′, so that the carrier output from the RF power amplifier 138′ is amplitude-modulated by the time-varying envelope signal from the current supply terminal.

Along the path for the delayed IQ modulated signal processing, the architecture of transmitter of the present invention comprises a delay control unit 132, a plurality of digital-to-analog converters 136, a IQ-modulator 137, a tunable gain amplifier 138 and a feedback control unit 150, wherein the feedback control unit 150 comprises an envelope detector 151, an analog-to-digital converter 152 and a second pre-distorter 153. The envelope detector 151 detects the output terminal of the RF power amplifier 138′ to produce the feedback envelope signal, the feedback envelope signal is digitized through the analog-to-digital converter 152, and the digitized feedback envelope signal together with the delayed digital envelope signal from the envelope generator is received by the second pre-distorter 153.

The present invention has the input IQ signals passing the delay control unit 132, and then has the delay-corrected IQ signals converted to the corresponding analog signals through the plurality of digital-to-analog converters 136, thereby producing the IQ-modulated carrier with the IQ-modulator 137, as a signal at the RF input terminal of the RF power amplifier 138′ after amplification by the tunable gain amplifier 138. The gain of the above-described tunable gain amplifier 138 is determined by the output of the second pre-distorter 153, which receives the output signal from the analog-to-digital converter 152 (digitized feedback envelope signal) and the output delayed signal from the envelope generator 131 (digital envelope signal), to produce a control signal for controlling the gain of the tunable gain amplifier 138. In different embodiments of the present invention, it is as well that the input IQ signals pass the second pre-distorter at first and the output signals are then input to the envelope generator and the plurality of digital-to-analog converters, respectively. In different embodiments of the present invention, it is as well that the input IQ signals pass the delay control unit at first and the output signals are then input to the envelope generator and the plurality of digital-to-analog converters, respectively. After a detailed description of the preferred embodiments of the present invention, it will be appreciated by those skilled in the art that various changes and modifications can be performed without departing the scope and spirit of the appended claim, while the present invention is not limited to the implementation of the embodiments set forth in the specification.

What is claimed is:

1. A transmitter, comprising:
an RF power amplifier, having a power supply terminal, an input terminal and an output terminal;
a first modulator, coupled to the power supply terminal of said RF power amplifier, said first modulator using the digital delta-sigma modulation technique to generate an envelope signal to supply to said power supply terminal; and
a second modulator, coupled to the input terminal of said RF power amplifier, said second modulator using the pre-distortion technique to process and generate an IQ-modulated carrier to supply to said input terminal.

2. The transmitter of claim 1, wherein said first modulator comprises a delta-sigma modulator, a switched amplifier and a low-pass filter.

3. The transmitter of claim 2, wherein said delta-sigma modulator receives the digital envelope signal generated from an envelope generator.

4. The transmitter of claim 3, wherein said envelope generator receives an IQ signal or an output signal generated from a pre-distorter, and said pre-distorter receives an IQ signal.

5. The transmitter of claim 1, further comprising: an envelope generator, coupled to the input terminal of the first modulator, for generating the corresponding digital envelope signal of the desired modulated signal.

6. The transmitter of claim 5, wherein said first modulator comprises: a delta-sigma modulator, for receiving the digital envelope signal and modulating it to be a two-stage signal.

7. The transmitter of claim 6, wherein said first modulator comprises: a switched amplifier for amplifying the two-stage signal, the amplified two-stage signal passing a low-pass filter to reduce to an amplified analog envelope signal for modulating the power supply terminal of said RF power amplifier.

8. The transmitter of claim 6, wherein said delta-sigma modulator is selected from the group consisting of an analog delta-sigma modulator, an analog pulse-width modulator, an analog multi-stage delta-sigma modulator, a digital delta-sigma modulator, a digital pulse-width modulator and a digital multi-stage delta-sigma modulator.

9. The transmitter of claim 5, wherein said first modulator comprises: a delta-sigma modulator for receiving the digital envelope signal and modulating the digital envelope signal to an at least two-stage signal.

10. The transmitter of claim 6, wherein said first modulator comprises: an at least one bit control current source, for converting the at least two-stage signal to a controlled current, the controlled current passing a low-pass filter to be the current supply for the power supply terminal.

11. The transmitter of claim 1, wherein said second modulator comprises a pre-distorter, a plurality of digital-to-analog converters and an IQ-modulator.

12. The transmitter of claim 11, wherein said pre-distorter has the circuitry functions including changing the IQ baseband signal, the envelope signal, the phase signal or the amplitude of the RF carrier.

13. The transmitter of claim 1, further comprising: a delay control unit, for coordinating the synchronization between said first modulator and said second modulator.

14. The transmitter of claim 1, further comprising: a feedback control unit, for detecting the output terminal of said RF power amplifier to obtain a feedback signal and processing the feedback signal and a digital envelope signal from an envelope generator with pre-distortion to modulate the gain of said input terminal.

15. The transmitter of claim 14, wherein said feedback control unit comprises: an envelope detector, for detecting said output terminal to generate the feedback signal; an analog-to-digital converter, for digitizing the feedback signal; and a pre-distorter, for receiving the digitized feedback signal and the digital envelope signal from the envelope generator to control a tunable gain amplifier, the tunable gain amplifier coupled to said input terminal.

16. The transmitter of claim 1, wherein said power supply terminal receives a low-frequency envelope signal.

17. The transmitter of claim 1, wherein said input terminal receives a phase-modulated carrier that is provided with a time-varying envelope.

18. The transmitter of claim 1, wherein said RF power amplifier is selected from the group consisting of class-A, class-B, class-AB, class-C, class-D, class-E or class-F amplifier circuits.

19. A modulation method for an RF power amplifier, applying to a transmitter, the modulation method for an RF power amplifier comprising:
generating an envelope signal with the digital delta-sigma modulation technique, to modulate the power supply terminal of said RF power amplifier; and
processing and generating an IQ-modulated carrier with pre-distortion technique, to modulate the input terminal of said RF power amplifier.

20. The modulation method for an RF power amplifier of claim 19, further comprising: processing the corresponding envelope signal of the desired modulated signal with a digital delta-sigma modulator.

21. The modulation method for an RF power amplifier of claim 19, further comprising: generating a phase-modulated and envelope-modulated driving signal with a combination of a pre-distorter, a plurality of digital-to-analog converters and an IQ-modulator.

22. The modulation method for an RF power amplifier of claim 19, further comprising: coordinating the synchronization between a first modulator and a second modulator with a delay control.

23. The modulation method for an RF power amplifier of claim 19, further comprising: detecting the output terminal of said RF power amplifier to obtain a feedback signal; and processing the feedback signal with pre-distortion to modulate the gain of said input terminal.

24. The modulation method for an RF power amplifier of claim 19, further comprising: controlling an at least one bit control current source with at least two-stage modulation, to convert the envelope signal to the current supply for said power supply terminal.

25. A transmitter, comprising:
a first modulator, receiving the envelope signal for the desired modulated signal and modulating it to be a two-stage signal, to generate a low-frequency envelope signal for the desired modulated signal;
a second modulator, receiving the desired modulated signal and processing it with pre-distortion, to generate a phase-modulated carrier that is characterized by a time-varying envelope; and
an RF power amplifier, receiving the low-frequency envelope signal for the desired modulated signal as the voltage supply for the RF power amplifier, and receiving the phase-modulated carrier that is characterized by a time-varying envelope as an RF input signal for the RF power amplifier, to generate an amplified RF modulated signal.

26. The transmitter of claim 25, wherein said first modulator comprises a delta-sigma modulator, a switched amplifier and a low-pass filter.

27. The transmitter of claim 26, wherein said delta-sigma modulator is selected from the group consisting of an analog delta-sigma modulator, an analog pulse-width modulator, an analog multi-stage delta-sigma modulator, a digital delta-sigma modulator, a digital pulse-width modulator and a digital multi-stage delta-sigma modulator.

28. The transmitter of claim 25, further comprising: an envelope generator, for generating the corresponding digital envelope signal of the desired modulated signal and supplying the digital envelope signal to said first modulator.

29. The transmitter of claim 25, wherein said second modulator comprises a pre-distorter, a plurality of digital-to-analog converters and an IQ-modulator.

30. The transmitter of claim 29, wherein said pre-distorter has the circuitry functions including changing the IQ baseband signal, the envelope signal, the phase signal or the amplitude of the RF carrier.

31. The transmitter of claim 25, wherein said RF power amplifier is selected from the group consisting of class-A, class-B, class-AB, class-C, class-D, class-E or class-F amplifier circuits.

32. A baseband processor, used in a transmitter, the baseband processor comprising:
an envelope generator, for generating the corresponding digital envelope signal of the desired modulated signal;
a delta-sigma modulator, for receiving the digital envelope signal and modulating it to be a two-stage signal;
a switched amplifier for amplifying the two-stage signal;
a low-pass filter, for receiving the amplified two-stage signal and reducing it to an amplified analog envelope signal; and
a pre-distorter, for compensating the nonlinear relation between the input and output signals of the microwave transmitter, thereby improving the parameters such as the modulation accuracy and the linearity.

33. The baseband processor of claim 32, wherein said delta-sigma modulator is selected from the group consisting of an analog delta-sigma modulator, an analog pulse-width modulator, an analog multi-stage delta-sigma modulator, a digital delta-sigma modulator, a digital pulse-width modulator and a digital multi-stage delta-sigma modulator.

34. The baseband processor of claim 32, wherein said pre-distorter has the circuitry functions including changing the IQ baseband signal, the envelope signal, the phase signal or the amplitude of the RF carrier.

35. The baseband processor of claim 32, wherein said transmitter comprises a transceiver chip, the transceiver chip coupled to said baseband processor for operation.

36. The baseband processor of claim 32, further comprising: a plurality of digital-to-analog converters, for converting the output signal of said pre-distorter to the corresponding analog signal.

37. The baseband processor of claim 32, wherein said envelope generator, said delta-sigma modulator and said pre-distorter are all realized with the baseband digital processing technique.

38. The baseband processor of claim 32, wherein said switched amplifier and said low-pass filter are both realized with the baseband analog signal processing technique.

39. The baseband processor of claim 36, wherein said digital-to-analog converters are realized with the baseband mixed signal processing technique.

40. A wireless transceiver chip, having a baseband processor, an RF processor and an RF power amplifier, the baseband processor comprising:
an envelope generator, for generating the corresponding digital envelope signal of the desired modulated signal;
a delta-sigma modulator, for receiving the digital envelope signal and modulating it to be a two-stage signal;
a switched amplifier for amplifying the two-stage signal;
a low-pass filter, for receiving the amplified two-stage signal and reducing it to an amplified analog envelope signal, the analog envelope signal supplied to said RF power amplifier; and
a pre-distorter, for compensating the nonlinear relation between the input and output signals of the microwave transmitter.

41. The wireless transceiver chip of claim 40, wherein said delta-sigma modulator of the baseband processor is selected from the group consisting of an analog delta-sigma modulator, an analog pulse-width modulator, an analog multi-stage delta-sigma modulator, a digital delta-sigma modulator, a digital pulse-width modulator and a digital multi-stage delta-sigma modulator.

42. The wireless transceiver chip of claim 40, wherein said pre-distorter of the baseband processor has the circuitry functions including changing the IQ baseband signal, the envelope signal, the phase signal or the amplitude of the RF carrier.

43. The wireless transceiver chip of claim 40, further comprising: a plurality of digital-to-analog converters, for converting the output signal of said pre-distorter to the corresponding analog signal.

44. The wireless transceiver chip of claim 40, wherein said envelope generator, said delta-sigma modulator and said pre-distorter are all realized with the baseband digital processing technique.

45. The wireless transceiver chip of claim 40, wherein said switched amplifier and said low-pass filter are both realized with the baseband analog signal processing technique.

46. The wireless transceiver chip of claim 43, wherein said digital-to-analog converters are realized with the baseband mixed signal processing technique.

47. The wireless transceiver chip of claim 40, wherein said RF power amplifier is selected from the group consisting of class-A, class-B, class-AB, class-C, class-D, class-E or class-F amplifier circuits.

48. The wireless transceiver chip of claim 40, wherein the error vector magnitude (EVM) for measuring the modulation accuracy, the adjacent channel power ratio (ACPR) for measuring the linearity, and the conversion efficiency (ConvEff) of DC power to RF power for measuring the transmitter efficiency are all independent of the output power of said RF power amplifier.

49. A transmitter, comprising:
an RF power amplifier, having a power supply terminal, an input terminal and an output terminal; and
a first modulator, coupled to the power supply terminal of said RF power amplifier and controlling the output power of the RF power amplifier, the first modulator comprising:
an envelope generator, for receiving an IQ signal to generate a digital envelope signal;
a delta-sigma modulator, for receiving the digital envelope signal and modulating it to be an at least two-stage signal; and
an at least one bit control current source, for converting the at least two-stage signal to a controlled current, the controlled current passing a low-pass filter to be the current supply for the RF power amplifier.

50. The transmitter of claim 49, further comprising: a second modulator, coupled to the input terminal of said RF power amplifier, said second modulator receiving an IQ signal, to generate an IQ-modulated carrier to supply to said input terminal.

51. The transmitter of claim 50, further comprising: a delay control unit, for coordinating the synchronization between said first modulator and said second modulator.

52. The transmitter of claim 49, further comprising: a feedback control unit, for detecting the output terminal of said RF power amplifier to obtain a feedback signal and processing the feedback signal and the digital envelope signal from the envelope generator with pre-distortion to modulate the gain of said input terminal.

53. The transmitter of claim 52, wherein said feedback control unit comprising: an envelope detector, for detecting said output terminal to generate the feedback signal; an analog-to-digital converter, for digitizing the feedback signal; and a pre-distorter, for receiving the digitized feedback signal and the digital envelope signal from the envelope generator to control a tunable gain amplifier, the tunable gain amplifier coupled to said input terminal.
